(19) United States
(12) Patent Application Publication
(10) Pub. No.: US 2025/0320607 A1
(43) Pub. Date: Oct. 16, 2025

(54) METHOD FOR MANUFACTURING COATED TUBULAR MEMBER HAVING AMORPHOUS CARBON DEPOSITION FILM FORMED ON INNER SURF ACE OF TUBULAR MEMBER

(71) Applicants: FUJI ELECTRIC CO., LTD., Kawasaki-shi, (JP); National University Corporation Tokai National Higher Education and Research System, Nagoya-shi (JP)

(72) Inventors: Yuya NAKASHIMA, Tokyo (JP); Kohei MURAKAMI, Sagamihara-city (JP); Hiroyuki KOUSAKA, Nagoya-shi (JP); Noritsugu UMEHARA, Nagoya-shi (JP); Takayuki TOKOROYAMA, Nagoya-shi (JP)

(73) Assignees: FUJI ELECTRIC CO., LTD., Kawasaki-shi (JP); National University Corporation Tokai National Higher Education and Research System, Nagoya-shi (JP)

(21) Appl. No.: 19/251,003

(22) Filed: Jun. 26, 2025

Related U.S. Application Data
(63) Continuation of application No. PCT/JP2024/004993, filed on Feb. 14, 2024.

(30) Foreign Application Priority Data
Feb. 15, 2023 (JP) 2023-021812

(51) Int. Cl. C23C 16/505; C23C 16/04; C23C 16/26; C23C 16/44

(52) U.S. Cl. CPC C23C 16/505; C23C 16/045; C23C 16/26; C23C 16/4412

(57) ABSTRACT

A steam turbine member suppresses adhesion of scale over a long period of time without impairing corrosion resistance or the like of a turbine. A method for manufacturing a coated tubular member having a deposited amorphous carbon film “m” formed on an inner surface of a tubular member, may include attaching lids to one end and another end of a tubular member, the lids including opening portions through which a gas can be introduced and discharged. The method may include depressurizing an inside of the tubular member by discharging the gas inside the tubular member from the opening portion of the lid on the one end; generating plasma inside the tubular member by applying a negative voltage to the tubular member and introducing a plasma-forming gas “g” into the tubular member from the opening portion of the lid on the other end; and introducing a raw material gas “g” of a deposited amorphous carbon film into the tubular member from the opening portion of the lid on the other end.

### CROSS-REFERENCE TO RELATED APPLICATIONS

This is a continuation application of international PCT Application No. PCT/JP2024/004993, filed on Feb. 14, 2024, which claims priority benefit based upon Japanese Patent Application No. 2023-021812, filed on Feb. 15, 2023, the contents of all of which are incorporated herein by reference.

### TECHNICAL FIELD

The present invention relates to a coated tubular member having a deposited amorphous carbon film formed on an inner surface of a tubular member.

### BACKGROUND ART

To generate power, a steam turbine used in geothermal power generation converts thermal energy in high-temperature and high-pressure geothermal steam into rotational force via a turbine blade. In this case, the steam, having lost energy, is reduced in temperature and pressure. When the temperature and the pressure of the high temperature and high-pressure geothermal steam are reduced, silica, calcium, iron sulfide, and the like, dissolved in the steam, precipitate and are deposited on a surface of the turbine blade. As the deposition progresses, a passage in which the geothermal steam flows becomes clogged. This is called scale deposition. Scale deposition can be a cause of unexpected power station shutdown, reduces the utilization factor of the geothermal power station, and greatly reduces power generation of the geothermal power plant. Therefore, there have been attempts to prevent scale deposition.

There are known techniques for preventing scale deposition on a turbine member such as a turbine blade by forming a deposited amorphous carbon film on a surface of the turbine member (see, for example, Patent Documents 1 and 2).

There is known a method for forming a deposited amorphous carbon film on a wall portion of a columnar hollow portion (see Patent Document 3). Specifically, Patent Document 3 discloses a method and a device which propagate a microwave to a wall portion of a columnar hollow portion of a film deposition target placed in a chamber to generate plasma, and form a film in a uniform thickness in a longitudinal direction of the columnar hollow portion by monitoring depletion of a raw material gas using a light-receiving optical system in real-time.

### REFERENCE DOCUMENT LIST

### Patent Documents

Patent Document 1: WO2021/112064A1
Patent Document 2: WO2022/107467A1
Patent Document 3: WO2014/157250A1

### SUMMARY OF THE INVENTION

### Problem to be Solved by the Invention

It has been reported that the techniques of Patent Documents 1 and 2 can form a deposited amorphous carbon film on an outer surface of a turbine member having a flat surface such as a turbine blade, and thereby efficiently prevent adhesion of scale.

In a geothermal power station, scale deposition becomes a problem not only on turbine members, but also on various apparatuses and inner surfaces of tubes with which a geothermal fluid comes into contact. As a method for forming a deposited amorphous carbon film on an inner surface of a tube, the method disclosed in Patent Document 3 has been used. However, this method is incapable of forming a deposited carbon film having a high anti-adhesion performance which satisfies conditions of a mathematical formula described in Patent Document 1.

There has been a demand for a method for forming a deposited carbon film having a property that is capable of preventing adhesion of scale on an inner surface of a tubular member.

### Means for Solving the Problem

As a result of earnest studies, the present inventors have conceived of a method in which a raw material gas is caused to flow only through an internal space of a tubular member, unlike a method in which a tubular member is disposed in a chamber for deposition like the conventional techniques, and have completed the present invention.

Specifically, according to one embodiment, the present invention relates to a method for manufacturing a coated tubular member having a deposited amorphous carbon film formed on an inner surface of a tubular member, including the steps of: attaching lids to one end and another end of a tubular member, the lids including opening portions through which a gas can be introduced and discharged; depressurizing an inside of the tubular member by discharging the gas inside the tubular member from the opening portion of the lid on the one end; generating plasma inside the tubular member by applying a negative voltage to the tubular member and introducing a plasma-forming gas into the tubular member from the opening portion of the lid on the other end; and introducing a raw material gas of a deposited amorphous carbon film into the tubular member from the opening portion of the lid on the other end.

The manufacturing method preferably includes a step of introducing a high-frequency wave into the tubular member simultaneously with or after the step of generating the plasma.

In the manufacturing method, the raw material gas preferably contains a hydrocarbon gas.

In the manufacturing method, the hydrocarbon gas is preferably methane.

In the manufacturing method, the negative voltage is preferably −1500 V to −50 V.

In the manufacturing method, the tubular member preferably has an inner diameter of approximately 12 mm or more and 1 m or less.

In the manufacturing method, the tubular member preferably has a length of 0.1 m or more.

In the manufacturing method, a ratio of a length of the tubular member to the inner diameter of the tubular member is preferably 6 or more.

In the manufacturing method, the lid which serves as an introduction port for the high-frequency wave is preferably formed of a material which can transmit the high-frequency wave.

According to another embodiment, the present invention relates to a coated tubular member manufactured by any one of the aforementioned manufacturing methods.

According to yet another embodiment, the present invention relates to a system for forming a deposited amorphous carbon film on an inner surface of a tubular member, including: lids which can be attached to one end and another end of a tubular member and which include opening portions through which a gas can be introduced and discharged; a device which introduces a raw material gas into the tubular member; an exhaust pump which discharges the gas inside the tubular member; and a power supply which applies a voltage to the tubular member.

The system preferably further includes a high-frequency wave generating device which introduces a high-frequency wave into the tubular member, wherein the lid which serves as an introduction port for the high-frequency wave is formed of a material which can transmit the high-frequency wave.

### Effects of the Invention

The present invention provides a method for manufacturing a coated tubular member, which can form a deposited amorphous carbon film on an inner surface of a tubular member. A deposited carbon film formed by this method has an ID/IG ratio, which indicates a ratio of sp² and sp³ structures, of 0 to 1.5, and thus can greatly reduce adhesion of silica scale. In addition, the manufacturing method according to the present invention is highly advantageous in that it is possible to form a deposited amorphous carbon film even on an inner surface of a tubular member having such a size and/or a structure with which it is difficult to house the tubular member in a depressurization chamber, and it has conventionally been impossible to manufacture a deposited amorphous carbon film, such as an elongated tubular member and a tubular member having a bulky structure on an outer surface thereof. In addition, in particular, the method comprising the step of introducing a high-frequency wave is advantageous particularly in the case of forming a deposited carbon film on an inner surface of a tubular member having a relatively small inner diameter, a light-transmittant tubular member of silicone, transparent ceramic, or the like, a tubular member formed of an organic material, or the like. Moreover, the method comprising the step of introducing a high-frequency wave can accelerate the rate of formation of a deposited carbon film by approximately 100 times or more.

### BRIEF DESCRIPTION OF THE DRAWING

FIG. 1 is a conceptual diagram showing a method for manufacturing a coated tubular member having a deposited amorphous carbon film formed on an inner surface of a tubular member according to an embodiment of the present invention.

### MODE FOR CARRYING OUT THE INVENTION

Hereinafter, an embodiment of the present invention will be described with reference to the drawing. However, the present invention is not limited to the embodiment described below.

According to one embodiment, the present invention relates to a method for manufacturing a coated tubular member having a deposited amorphous carbon film formed on an inner surface of a tubular member.

The tubular member refers to a hollow member formed of any material, in which one end portion and the other end portion in the longitudinal direction are open ends. For example, the tubular member may have an additional opening portion as long as the tubular member has opening portions in one end portion and the other end portion in the longitudinal direction, and may be a tube having a branch, but preferably is a continuously integral member. The shape and size of the tubular member can be specified by the inner diameter, the outer diameter, and the length. The inner diameter and the outer diameter may be constant, or may change in the longitudinal direction. In the case in which the inner diameter and the outer diameter change in the longitudinal direction, the inner diameter and the outer diameter may change stepwise, or change continuously. In particular, in the present invention, the dimensions and structure of the outer surface of the tubular member are not limited and may be determined as desired. Hence, the outer surface of the tubular member may be provided with a bulk structure. In addition, the tube axis of the tubular member may be linear or be curved. The shape of the tubular member in a section perpendicular to the tube axis thereof is preferably circular or oval, but it may be perpendicular or irregularly shaped. In addition, the member can be called a tubular member even when a member differs from that of a tube in general or a member which can be detached, such as a valve inside the tube.

The inner diameter of the tubular member may be, for example, 12 mm or more and may be 1 m or less. In the case in which the tubular member is a tube having a varying inner diameter, the variation width is not particularly limited, but it may be near 0 to 50% of the maximum diameter, for example. The length of the tubular member is not particularly limited, and the present invention is advantageous from the viewpoint that the present invention can be applied to an elongated tube of 0.5 m or more, for example. The length of the tubular member may be the length in the tube axis from one open end to the other open end. The length of the tubular member can be similarly defined no matter whether the tubular member is a linear tube or a tube having a curved shape.

In the case in which the tubular member is a member having a constant inner diameter, it is preferable that the ratio of the length to the inner diameter be 6 or more in some cases.

The tubular member is not particularly limited, and it may be, for example, a tubular metal member formed of a metal base material, a tubular resin member formed of a resin such as an organosilicon compound (silicone resin), or a tubular inorganic member mainly containing an inorganic substance such as glass or silicon. The type of the metal is not particularly limited, but it may be iron or an iron alloy. The type of resin is also not particularly limited, and any thermoplastic resin, thermosetting resin, fiber-reinforced plastic, or the like can be used. In particular, the material of a main body of a tubular member used in a geothermal power generation facility may be a stainless steel material, which is excellent in corrosion resistance, heat resistance, and wear resistance and is generally used in pipes of a geothermal power generation facility, and includes carbon steel, low-alloy steel, martensitic stainless steel, austenitic stainless steel, ferritic stainless steel, and the like, but it is not limited to these. Other examples of the base material include two-phase stainless steel, precipitation hardening stainless steel, Ni-based, Ti-based, or Co-based corrosion-resistant alloy, a non-iron metal (Cu and a Cu alloy, Al and an Al alloy), a resin such as vinyl chloride and silicone resin (including transparent resins such as a transparent silicone), an inorganic transparent member of glass, a silicon, a transparent ceramic, or the like. Note that a transparent member refers to a member having a visible light transmittance of at least 80% or more, and preferably 90% or more.

In the case in which the tubular member is a member in a geothermal power generation facility, examples of the tubular member may include tubes through which geothermal water flows, tubes of heat exchangers, valves such as a ball valve, a gate valve, and a butterfly valve, but the tubular member is not limited to these.

The inner surface of the tubular member may be such that a base material of a tubular metal member or a tubular resin member is exposed, and coating such as a hard layer which is not modified by generation of plasma, which will be described later, may be formed. Coating that is not modified by generation of plasma includes a ceramic coating and a metal coating, but they are not limited to these.

In the present Description, a member having a deposited amorphous carbon film formed on an inner surface of a tubular member is referred to as a coated tubular member.

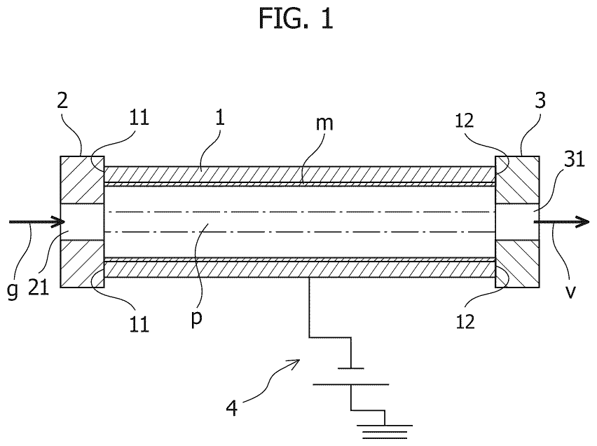

Next, a method for manufacturing a coated tubular member according to the present embodiment will be described with reference to FIG. 1. FIG. 1 shows an embodiment of forming a deposited amorphous carbon film “m” on an inner surface of a tubular member having constant inner diameter and outer diameter and a linear tube axis as an example to describe the manufacturing method. The manufacturing method includes the following steps:
(1) a step of attaching lids to one end and another end of a tubular member, the lids including opening portions through which a gas can be introduced and discharged;
(2) a step of depressurizing an inside of the tubular member by discharging the gas inside the tubular member from the opening portion of the lid on the one end;
(3) a step of generating plasma inside the tubular member by applying a negative voltage to the tubular member and introducing a plasma-forming gas into the tubular member from the opening portion of the lid on the other end; and
(4) a step of introducing a raw material gas of a deposited amorphous carbon film into the tubular member from the opening portion of the lid on the other end.

Optionally, the following step may be included simultaneously with the step (3) or after the step (3):
(3a) a step of introducing a high-frequency wave into the tubular member.

### (1) a Step of Attaching Lids

In the step (1), a first lid 2 provided with an introduction port 21 for a plasma-forming gas and raw material gas “g” is attached to a first end portion 11 of a tubular member 1. In addition, a second lid 3 provided with a discharge port 31 for an internal gas is attached to a second end portion 12 of the tubular member 1. As the tubular member 1, one described above can be used. The first lid 2 is configured to fit the shape of the first end portion 11 of the tubular member 1, and it is attached so that the gas does not leak from between the first lid 2 and the tubular member 1. Specifically, the first lid 2 may be made of a metal, and can be hermetically attached to the first end portion 11 of the tubular member 1 via an O-ring formed of silicone rubber or fluoro-rubber. The second lid 3 may also be configured generally in the same manner. When the tubular member 1 has a constant inner diameter and outer diameter in the longitudinal direction, the first lid 2 and the second lid 3 may have the same structure and may not need to be distinguished from each other. When the tubular member has no branch and includes the opening portion between the first end portion and the second end portion, a lid for covering the opening portion can be attached in the step (1). The lid for covering the opening portion may be one which does not have a port and can be attached so that the gas does not leak from the opening portion. When the tubular member has a branch, the tubular member can be understood to be a member having one or more additional end portions in addition to the first end portion and the second end portion. In this case, lids provided with introduction ports for the plasma-forming gas and the raw material gas, or lids provided with discharge ports for the internal gas, are attached to the one or more additional end portions. A specific example of a tubular member having a branch may be a Y-shaped tube (three-way tube), T-shaped tube, X-shaped (cross) tube, a tube having three or more branches, or any combination of these. Depending on the shape of the branch, there may be a plurality of end portions which serve as introduction ports for the plasma-forming gas and the raw material gas, and there may be a plurality of end portions which serve as discharge ports for the internal gas.

To the introduction port 21, a device, not shown, for introducing the plasma-forming gas and the raw material gas “g”, can be connected. Specifically, the device for introducing the plasma-forming gas and the raw material gas “g” may be a cylinder for the plasma-forming gas and the raw material gas g, including a flowmeter and a regulating valve. To the discharge port 31, an exhaust pump, not shown, can be connected.

### (2) a Step of Depressurizing the Inside of the Tubular Member

Subsequently, in the step (2), the inside of the tubular member 1 is depressurized. The depressurization can be conducted by discharging the internal gas from the discharge port 31 for the internal gas, and specifically can be conducted by discharging the internal gas using an exhaust pump such as a vacuum pump. The depressurization may be conducted to such an extent as that used in a general chemical vapor deposition method, and it is preferable to provide a manometer for measuring the internal pressure. Note that the step of depressurizing the inside of the tubular member 1 is conducted continuously in the following the steps (3) and (4).

### (3) a Step of Generating Plasma

In the following step (3), plasma “p” is generated inside the tubular member 1 by applying a voltage to the tubular member 1 and introducing a plasma-forming gas from the introduction port 21 of the first lid 2. Specifically, when the tubular member is a tubular metal member, a direct-current or alternate-current voltage can be applied continuously or in a pulsed manner by a grounded power supply 4 with a desired portion of the outer surface of the tubular metal member 1 as an electrode. It is preferable that a negative potential be applied to the tubular member 1, and the value of the negative potential may be approximately −1500 V to −50 V, and is preferably approximately −500 V to −300 V, but is not limited to a specific value.

When the tubular member is a tubular resin member, a cover member, made of metal, which can cover the outer surface of the tubular resin member is further provided, and a voltage can be applied in the same manner as in the tubular metal member using a desired portion of the outer surface of the cover member as an electrode.

The cover member may be a metal tube which is capable of encapsulating the tubular resin member in general. The type of metal is not particularly limited, and it may be a metal to which a voltage can be applied. More specifically, the cover member preferably has a size such that the inner diameter thereof is substantially equal to the outer diameter of the tubular resin member or is slightly larger than the outer diameter of the tubular resin member, such that the inner surface of the cover member and the outer surface of the tubular resin member can be in contact with each other, or be held close to each other. In addition, the length of the cover member is preferably a length which allows the cover member to cover at least an outer side of a region in which a deposited amorphous carbon film should be formed on the inner surface of the tubular resin member. The thickness of the cover member is not particularly limited as long as a voltage can be applied. Note that the metal-made cover member does not have to cover the entire surface of the outer surface. The metal-made cover member may be a member which can maintain a predetermined potential across a predetermined length near the outer surface of the tubular resin member, and may be a cover member which has a portion containing no metal, such as a metal mesh or a punched board.

When the tubular member is a tubular resin member, a step of attaching a cover member to the tubular resin member is conducted. This step can be conducted in parallel with the step (1) before the step (2), for example. When the cover member is attached to the tubular resin member, it is preferable that the tubular resin member and the cover member form a double tube and the entire outer surface of the tubular resin member be in contact with the cover member. Such a contact state is efficient for applying a desired negative voltage to the inner surface of the tubular resin member and generating sufficient plasma. However, it is possible to generate plasma even when the outer surface of the tubular resin member and the cover member are not in contact with each other or when only parts thereof are in contact with each other.

When the tubular member is a tubular resin member, the value of the negative voltage may be the same as described above, and it is preferable to apply the negative voltage while switching on and off in a pulsed manner. It is preferable that the application of the negative voltage be such that the time for which the voltage is on becomes about 0.1 to 20% of the entire time for which the processing is conducted in the step (3) and the following step (4).

Subsequently, argon (Ar) gas, which is a plasma-forming gas, is introduced from the introduction port 21 of the first lid 2, and also, the internal gas is discharged from the discharge port 3 of the second lid 3 continuously from the step (2). In this way, the argon gas can be caused to uniformly flow through the entire tubular member 1 in the longitudinal direction, and the plasma p which is in parallel with the tube axis of the tubular member 1 can be generated inside the tubular member 1. The flow rate of the Ar gas is preferably 10 to 70 sccm, and more preferably 30 to 50 sccm. At this time, the inner surface of the tubular member 1 can also be cleaned by causing a H₂ gas of about 40% to 60% of the flow rate of the Ar gas to flow simultaneously. The cleaning time in this case can be approximately 5 minutes to 15 minutes, for example.

### (4) a Step of Introducing a Raw Material Gas

After plasma is generated in the step (3), or simultaneously when plasma is generated, or before plasma is generated, the step (4) of introducing a raw material gas of a deposited carbon film from the introduction port 21 of the first lid 2 can be conducted. Hence, the step (3) and the step (4) may be simultaneously conducted, or the step (4) may be conducted prior to the step (3), in some cases. The raw material gas contains a hydrocarbon gas which serves as a carbon source to be contained in the deposited carbon film, and optionally serves as a hydrogen source, and a nitrogen gas which serves as a nitrogen source to be optionally contained in the deposited carbon film. As the hydrocarbon gas, methane, ethane, acetylene, or the like can be used, and in particular, methane gas is preferably used. The flow rate of the hydrocarbon gas is preferably 30 to 170 sccm, and more preferably 80 to 120 sccm. The introduction of the plasma-forming gas is conducted continuously from the step (3), and the discharge of the inner gas is conducted continuously from the step (2) and the step (3). This makes it possible to distribute the raw material gas across the entire tubular member 1 in the longitudinal direction, and uniformly form a deposited carbon film. That is, a configuration can be obtained in which the raw material gas more easily comes into contact with a surface on which a film is to be deposited than the chemical vapor deposition method in the conventional technique. Note that the introduction of the raw material gas is not limited to the introduction from the introduction port 21 of the first lid 2, but the raw material gas may be introduced from the second lid 3 provided with the discharge port 31, and may be introduced from both the introduction port 21 and the discharge port 31. When the raw material gas is introduced from both the introduction port 21 and the discharge port 31, an exhaust pump and a supply device for the raw material gas are connected to the discharge port 31.

When manufacturing a deposited carbon film containing carbon and hydrogen, the ratio of flow rates of the plasma-forming gas and the raw material gas at the time of introduction into the tubular member may be such that the plasma-forming gas and the raw material gas may be introduced, for example, such that the flow rate of the raw material gas reaches approximately 1 to 5 times the flow rate of the plasma-forming gas, and are preferably introduced such that the flow rate of the raw material gas is approximately 1.5 to 3 times the flow rate of the plasma-forming gas, depending on the properties of the deposited carbon film after the manufacture.

The time for which the present step is conducted is not particularly limited because the time varies depending on conditions such as the composition of the raw material gas and/or the introduction speeds of the plasma-forming gas and the raw material gas. The present step can be conducted over a time by which a deposited carbon film having a desired thickness can be formed. For example, for the application for preventing adhesion of scale, the thickness of the deposited carbon film is preferably 100 nm to 8 μm, and more preferably 1 to 6 μm. Hence, the time by which a deposited carbon film having a desired thickness can be formed may be confirmed through experiment in advance or the like, and the present step can be conducted for that time.

By the above-described operation, plasma is generated around the inner surface of the tubular member 1 or a hard layer optionally formed on the inner surface, and a hydrocarbon gas, for example, acetylene is introduced into the plasma-generated region. In this way, methane is decomposed by the plasma, and a deposited carbon film m containing hydrogen is formed on the tubular member 1 or the hard layer. During this film deposition, the hydrogen content in the deposited carbon film m can be controlled by controlling a negative voltage to be applied to the tubular member 1 to change the collision energy of decomposed methane, and to thus control the degree of decomposition of methane. Specific conditions under which a predetermined hydrogen content in the deposited carbon film “m” is achieved can be determined as appropriate by experiment in advance or the like by one skilled in the art.

According to yet another aspect, the present invention may be a system for conducting the above-described manufacturing method. The system comprises lids which can be attached to one end and another end of a tubular member and which include opening portions through which a gas can be introduced and discharged; a device which introduces a plasma-forming gas and a raw material gas into the tubular member; an exhaust pump which discharges the gas inside the tubular member; and a power supply which applies a voltage to the tubular member. Each member included in the system is as described in the above-described manufacturing method, and description thereof is omitted here. The system according to the present invention is capable of performing the above-described manufacturing method without using a vacuum chamber, which has been essential in the conventional manufacturing method.

The deposited amorphous carbon film formed by performing the above-described steps (1) to (4) has a relative intensity ratio (Id/Ig) of 0 to 1.5, or approximately 0.3 to 1.0 between intensities at a D band (near 1360 cm⁻¹) and at a G band (near 1580 cm⁻¹) of a Raman spectrum. It is said that Id/Ig correlates with a ratio of the Sp₂ structure and the Sp₃ structure in a deposited carbon film having an amorphous structure. The method and system according to the present invention can form a deposited amorphous carbon film having Id/Ig of the above-described value in the tubular member 1. This is particularly effective in preventing deposition of scale which becomes a problem on the inner surface of the tubular member 1.

The deposited amorphous carbon film formed may be a deposited carbon film consisting essentially of carbon alone. In this case as well, an element inevitably mixed in the production might be contained. A deposited carbon film containing hydrogen can be formed such that the hydrogen content is greater than 0 and is 60 atomic % or less. A deposited carbon film containing nitrogen can be formed such that the content of nitrogen is more than 0 and 30 atomic % or less. Whether or not a deposited carbon film contains hydrogen and/or nitrogen, the deposited carbon film according to the present invention might contain a small amount of oxygen due to the production method. In addition, in the case of forming a deposited carbon film on a hard layer, a compound contained in the hard layer might also be mixed in the deposited carbon film, and the deposited carbon film may contain a nonmetallic element such as silicon (Si), for example.

In a surface region of the deposited amorphous carbon film containing hydrogen produced by the embodiment of the present invention, the graphite amount G (%) in a carbon component and the hydrogen content H (at %) satisfy a relationship represented by the following formula (1):

$$H \geq 1.5118 \times G - 40.603 \qquad ( 1 )$$

wherein 0≤H≤60 and 0<G. When the hydrogen content H in the deposited carbon film is greater than 60 at %, the product exhibits characteristics that are not diamond-like carbon, but are plastic, and hence, the content H is preferably 60 at % or less. Here, the surface region of the deposited carbon film refers to a region within about 2 nm from the outermost surface of the deposited carbon film. The graphite amount G (%) in the carbon component refers to percentage of the number of graphite atoms to the total number of atoms of the carbon component contained in the surface region of the deposited carbon film. More specifically, the graphite amount G (%) in the carbon component refers to a percentage of the number of graphite atoms (mass) to the total number of atoms (total mass) of diamond and graphite contained in the carbon component contained in the surface region of the deposited carbon film. The graphite amount G (%) in the surface region can be obtained by X-ray absorption fine structure (XAFS) analysis. On the other hand, the hydrogen content H (at %) refers to percentage of the number of hydrogen atoms to the total number of atoms contained in the surface region of the deposited carbon film. The hydrogen content H (at %) in the surface region can be obtained by XAFS analysis and/or elastic recoil detection analysis (ERDA). Note that it is considered that a deposited amorphous carbon film which satisfies the relationship of formula (1) cannot be obtained by the method of Patent Document 3.

As an optional step, a step of forming an intermediate layer is preferably included between the step (3) and the step (4). The intermediate layer is used for improving adhesion between the tubular member and the deposited amorphous carbon film. The intermediate layer may contain, for example, a decomposition product of tetramethylsilane (TMS), and may be, for example, a layer of approximately 1 nm to 3 μm containing one or both of SiC and Si. The step of forming an intermediate layer can be conducted by causing a plasma-forming gas and a raw material gas to flow at a similar flow rate to the step (4), and additionally causing TMS to flow at a flow rate of approximately 40 to 60% of the plasma-forming gas. The time for which the step of forming an intermediate layer is conducted is not particularly limited, and the step can be conducted over a time by which an intermediate layer having a desired thickness can be formed.

In a certain embodiment, it is preferable that a high-frequency wave be propagated on an inner wall surface of a tubular member inside the tubular member simultaneously with the generation of plasma or after the generation in conducting the above-described steps (1) to (4). A high-frequency wave can be propagated on the inner wall surface of the tubular member by further including the step (3a) of introducing a high-frequency wave into the tubular member simultaneously with the step (3) of generating plasma or after the step (3).

Here, the high-frequency wave refers to an electromagnetic wave having a frequency of 1 MHz or more, and preferably is a microwave having a frequency of 300 MHz or more and 300 GHz or less. In general, it is most preferable to introduce a microwave having a frequency of 2.45 GHz into a tubular member; however, the high-frequency wave is not limited to a high-frequency wave having a specific frequency. The output of the high-frequency wave is preferably approximately 0.5 to 5 kW, and the duty ratio may be, for example, 1 to 5%. However, these conditions may vary depending on a relationship with an applied voltage at the time of generation of plasma, and the like, and are not limited to specific values.

In the present embodiment as well, the steps (1) to (3) can be conducted in the same manner as described above except that the material of lids used in the step (1) are changed to materials described below.

In the step (3a), the introduction of a high-frequency wave may be conducted when plasma is generated, and may be conducted simultaneously with the generation of plasma or after plasma is generated. The direction in which a high-frequency wave is introduced may be the same as or be opposite to the direction of introduction of a raw material gas. A high-frequency wave can also be introduced simultaneously from both end portions of the tube.

In the present embodiment, the system for forming a deposited amorphous carbon film on an inner surface of a tubular member further includes a device which generates a high-frequency wave including a microwave for introducing a high-frequency wave including a microwave. A high-frequency wave generating device is commercially available, and the introduction of a microwave into the tubular member can be conducted using a commercially available device. In addition, among the lids included in the system, the lid which is connected to the high-frequency wave generating device can be formed of a nonmetal material which can transmit a high-frequency wave. Specifically, a material having a transmittance of 80% or more, and preferably 90% or more for a high-frequency wave to be used can be employed, and includes quartz glass, sapphire glass, calcium fluoride, ceramic, a plastic, and the like. Note that the lid, which is not connected to the high-frequency wave generating device, may be a metal lid described in the above step (1), or may be a lid formed of a material which can transmit a high-frequency wave. In the present embodiment, the high-frequency wave including a microwave and the raw material gas can be introduced into the tubular member from the introduction port 21 of the first lid 2. Hence, a device for introducing the raw material gas may be connected to an introduction tube portion for a high-frequency wave which extends from the device which generates a high-frequency wave including a microwave to the lid such that the raw material gas can be supplied into the tubular member.

When conducting the step (3a) as well, the step (4) can be conducted in the same manner as described above. Note that when conducting the optional step of forming an intermediate layer, a microwave is not introduced in this step.

According to the manufacturing method comprising the step (3a) of introducing a high-frequency wave, it becomes possible to improve the rate of formation of a deposited amorphous carbon film by about 100 times or more, enabling more efficient film deposition. In addition, the manufacturing method comprising the step (3a) is particularly advantageous in forming a deposited amorphous carbon film on a relatively thin tubular member having an inner diameter of about 50 mm or less and on an inner surface of a light-transmittant tubular member.

The manufacturing method according to the present invention makes it possible to form a deposited amorphous carbon film having a generally uniform thickness over a tubular member in a longitudinal direction. In addition, the manufacturing method according to the present invention makes it possible to manufacture a deposited amorphous carbon film having a smooth surface and to achieve a maximum height roughness Rz of approximately 6.3 μm or less. The maximum height roughness Rz may be 1.0 μm or more, and may be 2.0 μm or more, but is not particularly limited. The maximum height roughness Rz refers to a value measured with a stylus-type surface roughness tester.

The method for manufacturing a coated tubular member according to the embodiment of the present invention makes it possible to form a deposited amorphous carbon film on an inner surface of a tubular member using the tubular member itself as a depressurization chamber without using a chamber capable of housing a target on which to form a deposited film therein, which has conventionally been essential in conducting a chemical vapor deposition method. This makes it possible to form a deposited amorphous carbon film on inner surfaces of an elongated tube, a tube having a bulky member attached to an outer surface thereof, and the like, which have conventionally been difficult to manufacture in practice.

### EXAMPLES

Hereinafter, the present invention will be described in more detail with reference to Examples. However, the present invention is not limited to the following Examples.

### Example 1

A coated tubular metal member having a deposited amorphous carbon film (DLC) formed on an inner surface of a tubular metal member was manufactured. As the tubular metal member, a tubular metal member which was formed of martensitic stainless steel (SUS 420J1) and which had an inner diameter of 16 mm and a length of 500 mm was prepared. In the present example, a hard layer was not provided. The lids were made of a metal and had a structure maintaining a hermetic seal using an O-ring. To the tubular metal member, −400V was applied. As a plasma-forming gas, Ar gas was used, and as a raw material gas, methane gas was used. The Ar gas and acetylene gas were introduced into the tubular metal member at flow rates of 40 sccm and 100 sccm, respectively, followed by processing for 30 minutes. In this way, the coated tubular metal member having the deposited amorphous carbon film formed on the inner surface of the tubular metal member was obtained. The value of Id/Ig of the deposited amorphous carbon film was 0.75. The film, which was generally uniform on the tube in the longitudinal direction, was obtained.

### Example 2

Coated tubular metal members having deposited amorphous carbon films (DLC) formed on inner surfaces of tubular metal members were manufactured using a manufacturing method which included a step of introducing a high-frequency wave and a manufacturing method which did not include this step. As the tubular metal members, a tubular metal member which was formed of two-phase stainless steel (SUS 329J4L) composed of an austenite phase and a ferrite phase and which had an inner diameter of 16 mm and a length of 100 mm was prepared. The diameter of this tube was equal to that of a tube for a heat exchanger used in geothermal binary power generation. As a microwave generating device, MMG-213VP (Ohta Electronics Co., Ltd.) was used. The lid connected to the microwave generating device was made of quartz glass and had a structure maintaining with a hermetic seal using an O-ring. The lid on the other side was the same as in Example 1. The lid made of quartz glass was used to irradiate the inside of the tubular metal member with the microwave through transmission. To the tubular metal member, bias voltage of −400 V with frequency of 50 kHz and duty ratio of 95% was applied to generate plasma. The microwave was set to an output of 1 kW, frequency of 2.45 GHz, and duty ratio of 2.5% and was introduced after the plasma was generated. As the raw material gas, Ar gas and acetylene gas were introduced into the tubular metal member under the same conditions as in Example 1. The pressure inside the tubular metal member at this time was 75 Pa.

As a result of observing how the plasma was formed during film deposition, light emission derived from the plasma from the tubular metal member was observed in both cases in which the microwave was introduced and in which the microwave was not introduced, so that it was confirmed that the plasma was formed in the tubular metal members. In addition, in the case in which the microwave was introduced, the light emission was more intense than in the case in which the microwave was not introduced, so that it was confirmed that plasma with higher density was formed (not shown). When the tubular metal member after the film deposition was cut in the tube longitudinal direction and observed, the entire inner surface of the tubular metal member had turned black, so that it was confirmed that the deposited amorphous carbon film was formed on the entire inner surface of the tubular metal member (not shown).

### REFERENCE SYMBOL LIST

1 Tubular member
2,3 Lid
4 Power supply
11, 12 End portion of tubular member
21,31 Port
m Deposited carbon film
p Plasma
g Plasma-forming gas and raw material gas
v Exhaust

What is claimed is:

1. A method for manufacturing a coated tubular member having a deposited amorphous carbon film formed on an inner surface of a tubular member, comprising steps of:
attaching lids to one end and another end of a tubular member, the lids including opening portions through which a gas can be introduced and discharged;
depressurizing an inside of the tubular member by discharging the gas inside the tubular member from the opening portion of the lid on the one end;
generating plasma inside the tubular member by applying a negative voltage to the tubular member and introducing a plasma-forming gas into the tubular member from the opening portion of the lid on the other end;
introducing a raw material gas of a deposited amorphous carbon film into the tubular member from the opening portion of the lid on the other end; and
introducing a high-frequency wave into the tubular member simultaneously with or after the step of generating plasma.

2. The method according to claim 1, wherein the raw material gas contains a hydrocarbon gas.

3. The method according to claim 2, wherein the hydrocarbon gas is methane.

4. The method according to claim 1, wherein the negative voltage is −1500 V to −50 V.

5. The method according to claim 1, wherein the tubular member has an inner diameter of approximately 12 mm or more and 1 m or less.

6. The method according to claim 1, wherein the tubular member has a length of 0.1 m or more.

7. The method according to claim 1, wherein a ratio of a length of the tubular member to the inner diameter of the tubular member is 6 or more.

8. The method according to claim 1, wherein the lid which serves as an introduction port for the high-frequency wave is formed of a material which can transmit the high-frequency wave.

9. A coated tubular member manufactured by the manufacturing method according to claim 1.

10. A system for forming a deposited amorphous carbon film on an inner surface of a tubular member, comprising:
lids which can be attached to one end and another end of a tubular member and which include opening portions through which a gas can be introduced and discharged;
a device which introduces a plasma-forming gas and a raw material gas into the tubular member;
an exhaust pump which discharges the gas inside the tubular member;
a power supply which applies a voltage to the tubular member; and
a high-frequency wave generating device which introduces a high-frequency wave into the tubular member.

11. The system according to claim 10, wherein the lid which serves as an introduction port for the high-frequency wave is formed of a material which can transmit the high-frequency wave.
